(19) United States
(12) Patent Application Publication
(10) Pub. No.: US 2020/0363716 A1
(43) Pub. Date: Nov. 19, 2020

(54) IMPRINT METHOD, IMPRINT APPARATUS, MANUFACTURING METHOD OF MOLD, AND ARTICLE MANUFACTURING METHOD

(71) Applicant: CANON KABUSHIKI KAISHA, Tokyo (JP)

(72) Inventor: Junichi Seki, Kawasaki-shi (JP)

(21) Appl. No.: 16/984,904

(22) Filed: Aug. 4, 2020

Related U.S. Application Data
(63) Continuation of application No. PCT/JP2019/004625, filed on Feb. 8, 2019.

(30) Foreign Application Priority Data
Feb. 26, 2018 (JP) 2018-032196

(51) Int. Cl. G03F 7/00; B29C 33/38; H01L 21/027

(52) U.S. Cl. CPC G03F 7/0002; H01L 21/0271; B29C 33/3842

(57) ABSTRACT

An imprint method of performing an imprint process for curing an imprint material in a state in which the imprint material on a shot region of a substrate and a pattern portion of a mold are in contact with each other, includes an adjusting step of adjusting, in accordance with shape information indicating a shape of a surface of at least one of the shot region and the pattern portion in a thickness direction of the pattern portion in the state, at least one of a distortion of the shot region in a planar direction orthogonal to the thickness direction and a distortion of the pattern portion in the planar direction.

### CROSS-REFERENCE TO RELATED APPLICATIONS

This application is a Continuation of International Patent Application No. PCT/JP2019/004625, filed Feb. 8, 2019, which claims the benefit of Japanese Patent Application No. 2018-032196, filed Feb. 26, 2018, both of which are hereby incorporated by reference herein in their entirety.

### BACKGROUND OF THE INVENTION

### Field of the Invention

The present invention relates to an imprint technique and, more specifically, an imprint method, an imprint apparatus, a manufacturing method of a mold, and an article manufacturing method.

### Background Art

An imprint technique is a technique that enables transfer of a nanoscale fine pattern, and has attracted attention as one of the lithography techniques for mass production of articles such as magnetic storage media and semiconductor devices. In the most common form of this technique, a mold having a fine concave-convex pattern formed thereon is brought into contact with an imprint material arranged on a substrate, the imprint material is cured in that state, and then the cured imprint material is separated from the mold.

In the lithography step using the imprint technique, as in the lithography step using an exposure apparatus, it is common to overlay a pattern to be newly formed on a pattern or a structure formed on a substrate in advance. Improving the overlay accuracy is important for improving the performance and yield of articles manufactured using the imprint technique.

Japanese Patent Laid-Open No. 2017-50428 describes that the distortion component of a shot region of a substrate at the time of holding the warped substrate by a substrate chuck is obtained, and the shape or the position of at least one of a mold and the substrate is controlled in accordance with the distortion component. Japanese Patent No. 5932286 describes that the overlay accuracy is improved by deforming a substrate by irradiating the substrate with light.

If there is unevenness on the surface of a substrate, when an imprint material on the substrate is brought into contact with the pattern portion of a mold, the pattern portion of the mold or the shot region of the substrate facing it can be deformed so as to have a flexure corresponding to the unevenness on the surface of the substrate. This flexure can cause shifts of the pattern formed on the pattern portion of the mold and the pattern formed on the shot region of the substrate from the designed positional relationship (the positional relationship in a planer direction). In addition, if there is unevenness on the surface of the pattern portion of the mold, when the imprint material on the substrate is brought into contact with the pattern portion, the pattern portion or the shot region of the substrate facing it can be deformed. Such a deformation can also cause shifts of the pattern formed on the pattern portion of the mold and the pattern formed on the shot region of the substrate from the designed positional relationship (the positional relationship in the planar direction).

FIG. 16 exemplarily shows a shot region 1600 of a substrate. The shot region 1600 can include at least one chip region 1602, a scribe line 1603, and a plurality of alignment marks 1601. The plurality of alignment marks 1601 can be arranged on the scribe line 1603. The pattern portion of a mold can include at least one chip region, a scribe line, and a plurality of alignment marks so as to correspond to the shot region 1600.

In an imprint process in which after the pattern portion of the mold is brought into contact with an imprint material arranged on the shot region 1600 of the substrate, the imprint material is cured to form a pattern made of a cured product of the imprint material, an alignment process is performed. In the alignment process, the relative position between the alignment mark on the shot region 1600 of the substrate and the alignment mark on the pattern portion of the mold is detected. Based on the detection result, the relative position, the relative shape, and the relative rotation between the substrate and the mold are adjusted, and the shape of at least one of the shot region and the pattern portion is adjusted.

In the alignment process as described above, even if a pattern shift in the planar direction occurs due to the contact between the imprint material on the substrate and the pattern portion of the mold, the relatively high overlay accuracy can be obtained in the vicinity of the region where the alignment mark exists. However, in a region away from the alignment mark, a pattern shift in the planar direction due to a local distortion of the pattern portion caused by the contact between the imprint material on the substrate and the pattern portion of the mold cannot be compensated.

Note that in Japanese Patent Laid-Open No. 2017-50428, a distortion caused by correcting the substrate by the substrate chuck is considered, but a pattern shift caused by the contact between the imprint material on the substrate and the pattern portion of the mold is not considered.

### SUMMARY OF THE INVENTION

The present invention provides a technique advantageous in improving the overlay accuracy.

One aspect of the present invention relates to an imprint method of performing an imprint process for curing an imprint material in a state in which the imprint material on a shot region of a substrate and a pattern portion of a mold are in contact with each other, and the imprint method comprises an adjusting step of adjusting, in accordance with shape information indicating a shape of a surface of at least one of the shot region and the pattern portion in a thickness direction of the pattern portion in the state, at least one of a distortion of the shot region in a planar direction orthogonal to the thickness direction and a distortion of the pattern portion in the planar direction.

Further features of the present invention will become apparent from the following description of exemplary embodiments with reference to the attached drawings.

### BRIEF DESCRIPTION OF THE DRAWINGS

FIG. 1 is a block diagram showing an imprint apparatus according to the first embodiment.

FIG. 2 is a flowchart illustrating the procedure of an imprint method according to the first embodiment.

FIG. 3A is a view exemplarily showing the arrangement of a substrate.

FIG. 3B is a view exemplarily showing the arrangement of the substrate.

FIG. 3C is a view exemplarily showing the arrangement of the substrate.

FIG. 4A is a view schematically showing the shape of a pattern portion in a thickness direction before a contact between an imprint material and the pattern portion.

FIG. 4B is a view schematically showing the shape of the pattern portion in the thickness direction after the contact.

FIG. 5A is a view schematically showing the distortion of the pattern portion in a planar direction before the contact between the imprint material and the pattern portion.

FIG. 5B is a view schematically showing the distortion of the pattern portion in the planar direction after the contact.

FIG. 5C is a view schematically showing the arrangement of alignment marks.

FIG. 6A is a view schematically showing the distortion of the pattern portion in the planar direction before the contact between the imprint material and the pattern portion.

FIG. 6B is a view schematically showing the distortion of the pattern portion in the planar direction after the contact.

FIG. 7A is a view schematically showing the pattern shift in the pattern portion before the contact between the imprint material and the pattern portion.

FIG. 7B is a view schematically showing the pattern shift of the pattern portion in the planar direction after the contact.

FIG. 7C is a view schematically showing the arrangement of the alignment marks.

FIG. 8A is a view schematically showing the pattern shift of the pattern portion in the planar direction before the contact between the imprint material and the pattern portion.

FIG. 8B is a view schematically showing the pattern shift of the pattern portion in the planar direction after the contact.

FIG. 9 is a block diagram showing an imprint apparatus according to the second embodiment.

FIG. 10 is a flowchart illustrating the procedure of an imprint method according to the second embodiment.

FIG. 11A is a view schematically showing the distortion of a pattern portion in a planar direction before a contact between an imprint material and the pattern portion.

FIG. 11B is a view schematically showing the distortion of the pattern portion in the planar direction after the contact.

FIG. 12A is a view schematically showing the pattern shift of the pattern portion in the planar direction before the contact between the imprint material and the pattern portion.

FIG. 12B is a view schematically showing the pattern shift of the pattern portion in the planar direction after the contact.

FIG. 13A is a view showing the unevenness of the surface of the substrate by gradation.

FIG. 13B is a view showing the unevenness of the surface of the pattern portion of the mold or the imprint material by gradation.

FIG. 14A is a view schematically showing the distortion of the pattern portion in the planar direction before the contact between the imprint material and the pattern portion.

FIG. 14B is a view schematically showing the distortion of the pattern portion in the planar direction after the contact.

FIG. 15A is a view schematically showing the pattern shift of the pattern portion in the planar direction before the contact between the imprint material and the pattern portion.

FIG. 15B is a view schematically showing the pattern shift of the pattern portion in the planar direction after the contact.

FIG. 16 is a view exemplarily showing the shot region of a substrate.

FIG. 17A is a view exemplarily showing an article manufacturing method.

FIG. 17B is a view exemplarily showing the article manufacturing method.

FIG. 17C is a view exemplarily showing the article manufacturing method.

FIG. 17D is a view exemplarily showing the article manufacturing method.

FIG. 17E is a view exemplarily showing the article manufacturing method.

FIG. 17F is a view exemplarily showing the article manufacturing method.

FIG. 18A is a view exemplarily showing an article manufacturing method.

FIG. 18B is a view exemplarily showing the article manufacturing method.

FIG. 18C is a view exemplarily showing the article manufacturing method.

FIG. 18D is a view exemplarily showing the article manufacturing method.

### DESCRIPTION OF THE EMBODIMENTS

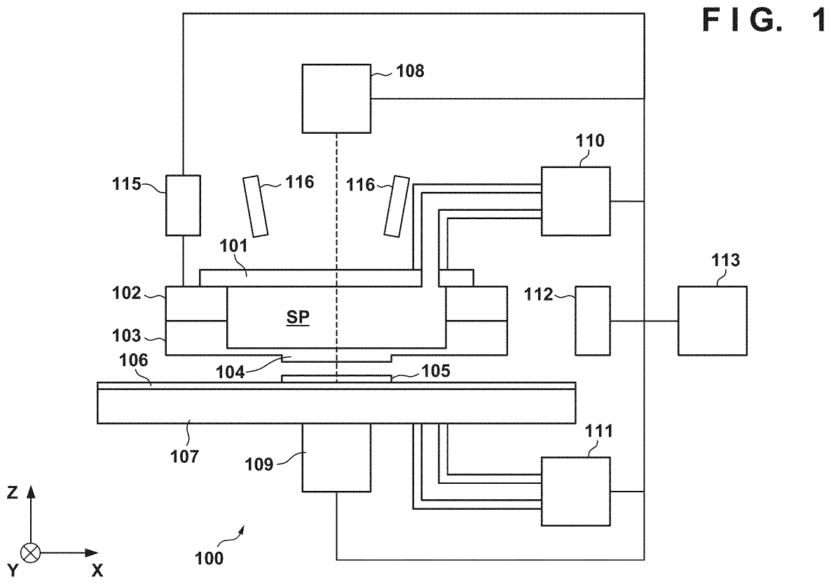

Exemplary embodiments of the present invention will be described below with reference to the accompanying drawings. FIG. 1 shows the arrangement of an imprint apparatus 100 according to the first embodiment of the present invention. The imprint apparatus 100 performs an imprint process for curing an imprint material 105 in a state in which the imprint material 105 on a shot region of a substrate 106 and a pattern portion 104 of a mold 103 are in contact with each other. By curing the imprint material 105, a pattern made of a cured product of the imprint material 105 is formed.

As the imprint material, a curable composition (to be also referred to a resin in an uncured state hereinafter) to be cured by receiving curing energy is used. As the curing energy, an electromagnetic wave, heat, or the like can be used. The electromagnetic wave can be, for example, light selected from the wavelength range of 10 nm (inclusive) to 1 mm (inclusive), for example, infrared light, a visible light beam, or ultraviolet light. The curable composition can be a photo-curable composition which is cured by light irradiation. Alternatively, the curable composition can be a thermosetting composition which is cured by heating or a thermoplastic composition which is cured by cooling. Among compositions, a photo-curable composition contains at least a polymerizable compound and a photopolymerization initiator, and may further contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component.

The imprint material can be arranged on the substrate in the form of droplets or in the form of an island or film formed by connecting a plurality of droplets. Alternatively, the imprint material can be applied or arranged on the substrate by a method such as a spin coating method, a slit coating method, or a screen printing method. The viscosity (the viscosity at 25° C.) of the imprint material can be, for example, 1 mPa·s (inclusive) to 100 mPa·s (inclusive). As the material of the substrate, for example, glass, a ceramic, a metal, a semiconductor, a resin, or the like can be used. A member made of a material different from the substrate may be provided on the surface of the substrate, as needed. The substrate is, for example, a silicon wafer, a compound semiconductor (GaN or SiC) wafer, or silica glass.

In the specification and the accompanying drawings, directions will be indicated on an XYZ coordinate system in which directions parallel to the surface of the substrate 106 are defined as the X-Y plane, and the thickness direction of each of the substrate 106 and the mold 103 is defined as the Z direction. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and a posture is information that can be specified by values on the θX-, θY-, and θZ-axes. Positioning means controlling the position and/or posture. Alignment can include controlling the position and/or posture of at least one of the substrate and the mold.

The imprint apparatus 100 can include a substrate chuck 107, a substrate driving mechanism 109, a substrate back pressure adjuster 111, a dispenser 112, a control unit 113, a mold chuck 102, a mold driving mechanism 115, a mold back pressure adjuster 110, a curing unit 108, and a measuring device 116. The substrate chuck 107 holds (chucks) the substrate 106. The substrate driving mechanism 109 drives the substrate chuck 107 such that the substrate 106 is driven about a plurality of axes (for example, three axes of the X-, Y-, and θZ-axes, and preferably, six axes of the X-, Y-, Z-, θX-, θY-, and θZ-axes). The substrate back pressure adjuster 111 supplies a pressure (negative pressure) for the substrate chuck 107 holding (chucking) the substrate 106 to the substrate chuck 107. The substrate chuck 107 can include a plurality of sectioned suction regions, and the substrate back pressure adjuster 111 can individually adjust the pressure for each of the plurality of sections.

The mold 103 includes the pattern portion 104, and the pattern portion 104 can include a pattern formed by a convex portion and a concave portion. The pattern portion 104 can form a mess projecting more than the peripheral portion. In a state in which the imprint material on the substrate 106 and the pattern portion 104 are in contact with each other, the surface tension can suppress the uncured imprint material 105 from protruding to the outside of the pattern portion 104. The material of the mold 103 is not particularly limited, but can be formed by, for example, a metal, silicon, a resin, or a ceramic. When a photo-curable composition is employed as the imprint material 105, the mold 103 can be made of a light transmissive material such as quartz, sapphire, or a transparent resin.

The mold chuck 102 holds (chucks) the mold 103. The mold driving mechanism 115 drives the mold chuck 102 such that the mold 103 is driven about a plurality of axes (for example, three axes of the Z-, θX-, and θY-axes, and preferably, six axes of the X-, Y-, Z-, θX-, θY-, and θZ-axes). The mold chuck 102 can be provided with a window member 101 for defining a closed space SP used to apply a pressure onto the back surface (the surface opposite to the surface on which a pattern to be transferred to the substrate 106 or the imprint material has been formed) of the mold 103. The mold back pressure adjuster 110 adjusts the pressure in the closed space SP. For example, when the mold back pressure adjuster 110 increases the pressure in the closed space SP, the pattern portion 104 can be deformed so as to have a downward convex shape. In addition, when the mold back pressure adjuster 110 decreases the pressure in the closed space SP, the pattern portion 104 can be deformed to have a concave shape.

The curing unit 108 applies curing energy to the imprint material 105 in a state in which the imprint material 105 on the shot region of the substrate 106 and the pattern portion 104 of the mold 103 are in contact with each other and the concave portion of the pattern portion 104 is sufficiently filled with the imprint material 105. Thus, the imprint material 105 is cured.

The measuring device 116 measures the relative position between an alignment mark provided on the shot region of the substrate 106 and an alignment mark provided on the pattern portion 104 of the mold 103. A plurality of alignment marks are provided on the shot region, and a plurality of alignment marks are provided on the pattern portion 104 so as to correspond to the alignment marks on the shot region. By utilizing these alignment marks, it is possible to obtain information indicating the relative position and the relative rotation, and further the relative shape difference between the shot region and the pattern portion 104. Based on the information, the shot region and the pattern portion 104 can be aligned. At least one of the substrate driving mechanism 109, the mold driving mechanism 115, a substrate deforming mechanism (not shown) for deforming the shot region, and a mold deforming mechanism (not shown) for deforming the pattern portion 104 can be used for the alignment.

The imprint material 105 can be applied or arranged on the substrate 106 by a method such as a spin coating method, a slit coating method, or a screen printing method in the outside of the imprint apparatus 100. Alternatively, the imprint material 105 can be supplied or arranged on the substrate 106 by the dispenser 112 provided in the imprint apparatus 100. The dispenser 112 can supply or discharge the imprint material 105 onto the substrate 106 by a method such as, for example, a pneumatic method, a mechanical method, or an inkjet method. These methods are advantageous in adjusting the distribution of the imprint material 105 supplied onto the substrate 106 in accordance with the density of the pattern to be formed on the substrate 106. By supplying the imprint material 105 onto the substrate 106 and bringing the imprint material 105 into contact with the pattern portion 104 of the mold 103 in a shot time, it is possible to use the imprint material 105 having high volatility and low viscosity. Therefore, the filling time (the filling time of the imprint material 105 to the pattern of the pattern portion 104) can be shortened.

An operation of the imprint apparatus 100 will be exemplarily described below. This operation is controlled by the control unit 113. First, the substrate 106 with the imprint material 105 applied thereon is supplied to the imprint apparatus 100, or the dispenser 112 arranges the imprint material 105 on one or a plurality of shot regions of the substrate 106. Then, the shot region on which a pattern is to be formed is positioned immediately below the pattern portion 104 of the mold 103 by the substrate driving mechanism 109.

Next, the pattern portion 104 is deformed so as to have a downward convex shape by increasing the pressure in the closed space SP by the mold back pressure adjuster 110. Then, in this state, the mold driving mechanism 115 drives the mold 103 so as to bring the imprint material 105 on the shot region into contact with the pattern portion 104. This operation may be performed by driving the substrate 106 by the substrate driving mechanism 109. After that, the mold back pressure adjuster 110 decreases the pressure in the closed space SP, so that the pattern portion 104 is returned to be flat and the contact region between the imprint material 105 and the pattern portion 104 is enlarged.

After the entire region of the pattern portion 104 is brought into contact with the imprint material 105 and the concave portion of the pattern portion 104 is sufficiently filled with the imprint material 105, the curing unit 108 supplies curing energy to the imprint material 105 to cure the imprint material 105. When the imprint material 105 is a photo-curable composition, light such as ultraviolet light can be used as the curing energy. When the imprint material 105 is a thermosetting composition, heat can be used as the curing energy. When the imprint material 105 is a thermoplastic composition, the energy for cooling the imprint material 105 can be used.

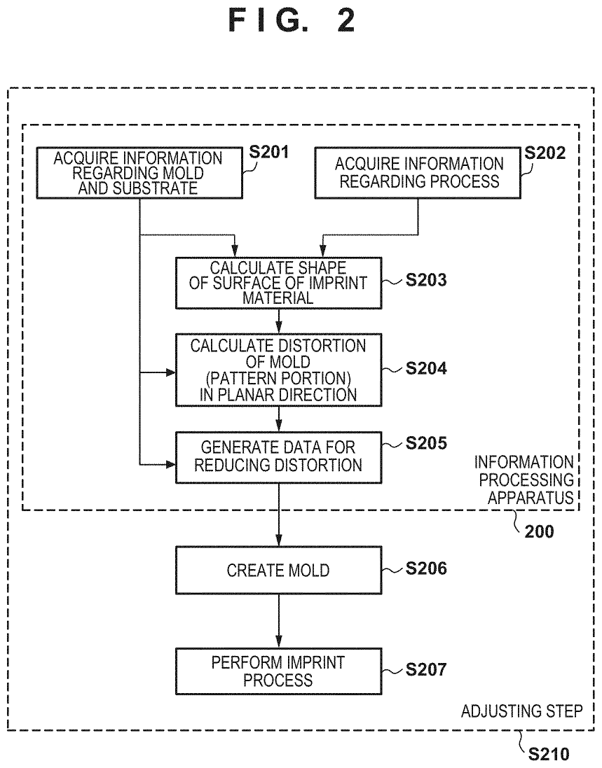

FIG. 2 illustrates the procedure of an imprint method S210 according to the first embodiment of the present invention. Steps S201 to S205 are included in an information processing step and, typically, can be performed by an information processing apparatus (computer) 200 installed with a program. An example in which the information processing step is performed by the information processing apparatus 200 will be described below. The information processing apparatus 200 can include a CPU, and a memory storing a program for performing steps S201 to S205. The program can be transferred via a telecommunication line, or provided via a memory medium such as a semiconductor memory or an optical disk. Note that the present invention does not exclude a case in which all or part of the information processing step is performed by manual calculation.

In step S201, the information processing apparatus 200 acquires member information which is information regarding the mold 103 and the substrate 106. The member information can include, for example, information on the shape of the mold 103 in the thickness direction (the position (height) distribution in the thickness direction) and the shape of the mold 103 in the planar direction (the direction orthogonal to the thickness direction). In addition, the member information can include information on the shape of the substrate 106 in the thickness direction and the shape of the substrate 106 in the planar direction. At least some of the information on the shape in the thickness direction and the information on the shape in the planar direction of each of the mold 103 and the substrate 106 may be prepared through measurement by a measuring apparatus such as an optical measuring apparatus or a stylus measuring apparatus. The information on the shape in the thickness direction and the information on the shape in the planar direction of each of the mold 103 and the substrate 106 can include information on the pattern included in each of the mold 103 and the substrate 106. The member information can further include information on the material, Young's modulus, Poisson's ratio, or the like of each of the mold 103 and the substrate 106. The shape of the object (such as the mold or the substrate) in the thickness direction is the shape of the object in a cross section parallel to the thickness direction, and the shape of the object in the planar direction is the shape of the object in a cross section parallel to the planar direction.

In step S202, the information processing apparatus 200 acquires process information regarding a process performed in the imprint apparatus 100. The process information can include, for example, the material, supply amount, distribution on the substrate 106, viscosity, surface energy, and contact angle with each of the mold 103 and the substrate 106, of the imprint material 105. In addition, the process information can include the pressing force of the mold 103 against the imprint material 105, the pressing time, the back pressure applied to the mold 103, the back pressure applied to the substrate 106, or the like.

In step S203, based on the information acquired in each of steps S201 and S202, the information processing apparatus 200 calculates the shape information indicating the shape of the surface of the pattern portion 104 in the thickness direction of the pattern portion 104 in a state (to be referred to as a “contact state” hereinafter) in which the imprint material 105 on the shot region of the substrate 106 and the pattern portion 104 of the mold 103 are in contact with each other. In this example, the shape of the surface of the imprint material 105 in the contact state is alternatively calculated as the shape information. Here, the shape of the surface of the imprint material 105 in the contact state can be regarded as coinciding with the shape of the surface of the pattern portion 104 in the contact state.

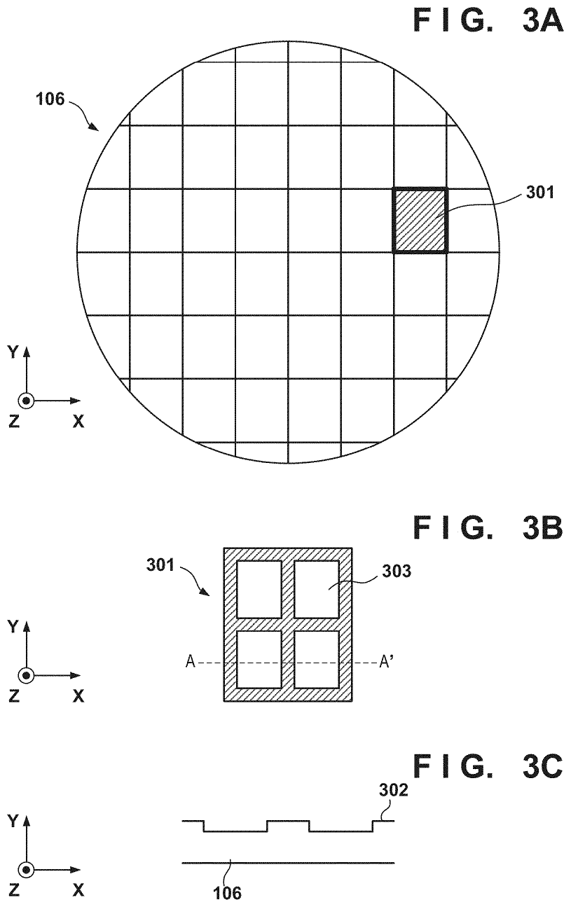

FIGS. 3A to 3C exemplarily show the structure of the substrate 106. FIG. 3A exemplarily shows the entire region of the substrate 106. The substrate 106 can include a plurality of shot regions 301. FIG. 3B exemplarily shows one shot region 301. FIG. 3C exemplarily shows a cross section taken along a line A-A′ in FIG. 3B. Each shot region 301 can include one or a plurality of chip regions 303. In addition, each shot region 301 can include a convex portion 302. In this example, the convex portion 302 is formed by a scribe line. The shot region 301 can have unevenness due to various causes. In one example, the shot region of the substrate 106 includes a patterned layer, and the shape of the shot region in the thickness direction in the contact state has unevenness formed by the patterned layer. The shape information can include information indicating the unevenness. The unevenness can be local unevenness whose one spatial cycle is defined by the dimension of the shot region 301 or the chip region 303.

The pattern portion 104 includes alignment marks, and the shape information can include information indicating the position (height) in the thickness direction for each of a plurality of portions located in a region of the pattern portion 104 where no alignment mark exists. Thus, also in the region where no alignment mark exists, it is possible to improve the overlay accuracy between the pattern on the substrate 106 and the pattern to be formed thereon by the imprint process (or the pattern of the pattern portion 104). This is advantageous in a case in which the pattern portion 104 has a local distortion in the contact state. Therefore, even if the numerical values of the overlay inspection are the same as in the conventional method, it is possible to improve the yield and the device performance.

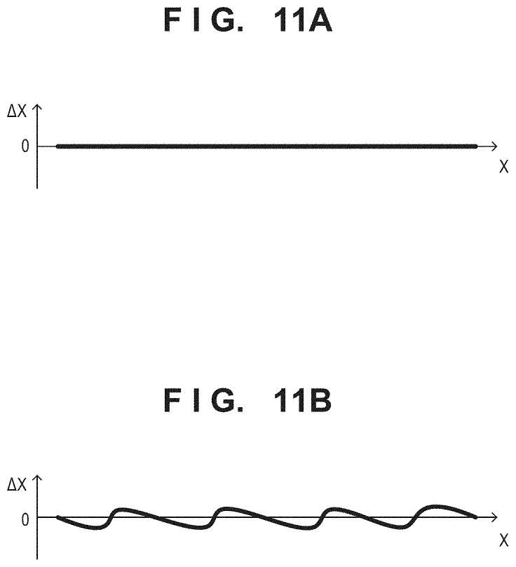

FIG. 4A schematically shows a state in which in the imprint apparatus 100, the imprint material 105 has been arranged by the dispenser 112 on the shot region 301 of the substrate 106 having the unevenness as exemplarily shown in FIGS. 3B and 3C. FIG. 4B schematically shows a state (contact state) in which the imprint material 105 shown in FIG. 4A is in contact with the pattern portion 104 of the mold 103. In the contact state, the pattern portion 104 has a shape corresponding to the shape of the surface of the substrate 106. However, since the imprint material 105 exists between the substrate 106 and the pattern portion 104 and the pattern portion 104 has an appropriate rigidity, the shape of the surface of the pattern portion 104 does not coincide with the shape of the surface of the substrate 106. In the example shown in FIG. 4B, the pattern portion 104 includes a slope 401. The shape of the surface of the pattern portion 104 can coincide with the shape of the surface of the imprint material 105 in contact with the surface of the pattern portion 104. FIG. 13A shows the unevenness of the surface of the substrate 106 shown in each of FIGS. 4A and 4B by gradation. FIG. 13B shows the unevenness of the surface of the pattern portion 104 of the mold 103 or the imprint material 105 by gradation.

The calculation in step S203 can be performed utilizing a simulation tool such as a fluid analysis tool or a structural analysis tool. Alternatively, the calculation in step S203 can be performed based on a prediction formula obtained from the relationship between the surface shape of the substrate and the surface shape of the cured imprint material arranged thereon in a sample manufactured in the past.

In step S204, the information processing apparatus 200 calculates the distortion of the pattern portion 104 of the mold 103 in the planar direction based on the member information acquired in step S201 and the surface shape of the imprint material 105 obtained in step S203. This calculation can be performed utilizing a simulation tool such as a structural analysis tool or the like. Alternatively, this calculation can be performed based on a prediction formula obtained based on the evaluation result of a sample manufactured in the past.

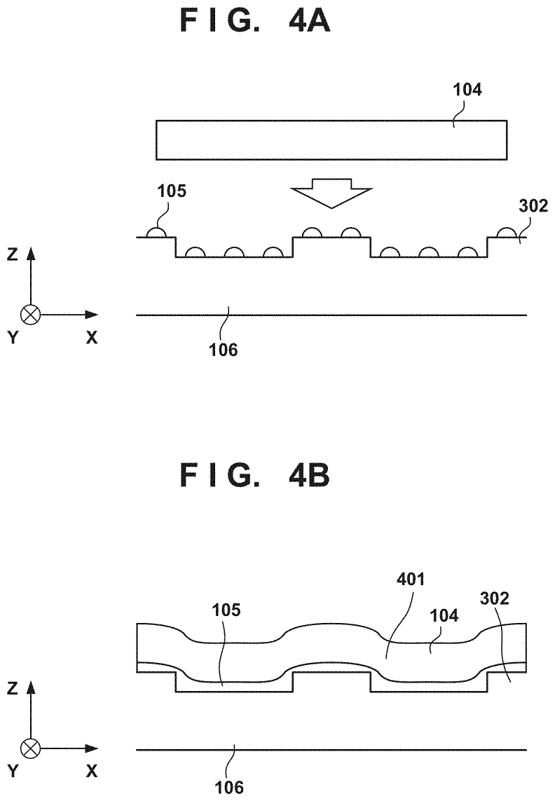

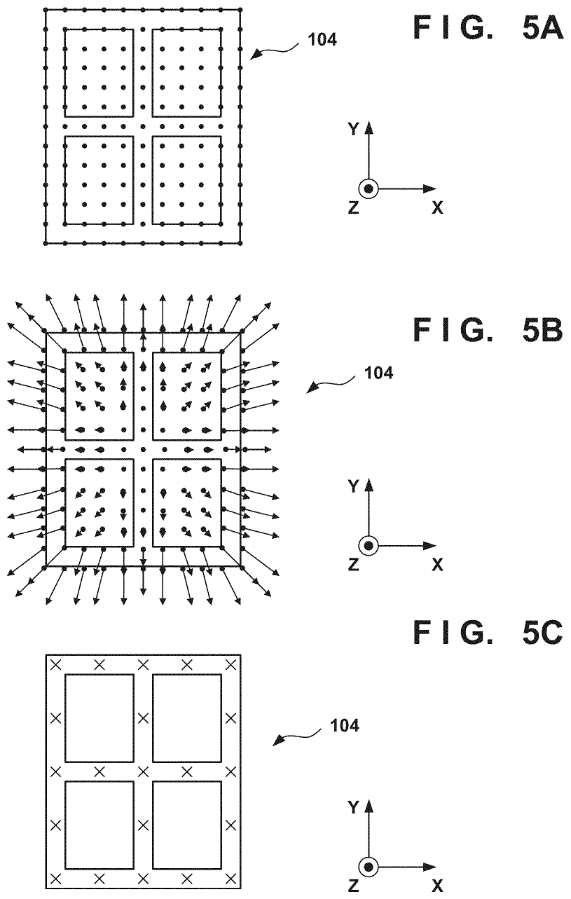

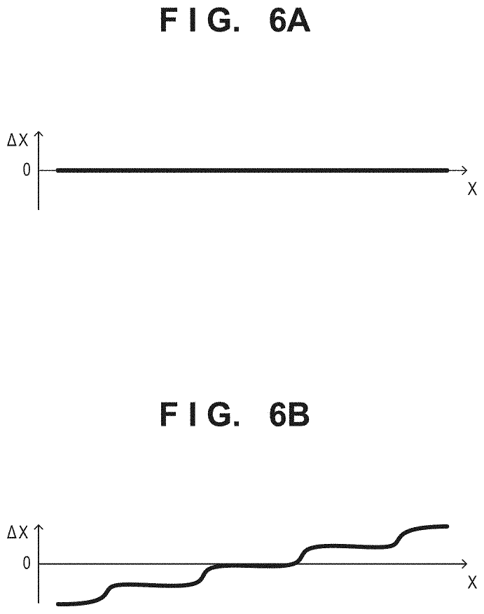

FIGS. 5A and 5B are plan views of the pattern portion 104 corresponding to FIGS. 4A and 4B, respectively. FIG. 5C is a plan view in which the arrangement of each alignment mark is indicated by an X mark. In FIG. 5A, each black circle exemplifies a point of interest in the pattern portion 104 in a state (non-contact state) in which the pattern portion 104 is not in contact with the imprint material 105 on the substrate 106. In FIG. 5B, the length and direction of each arrow exemplify the shift of the point of interest in the pattern portion 104 in a state (contact state) in which the pattern portion 104 is in contact with the imprint material 105 on the substrate 106, that is, the distortion of the pattern portion 104. In this example, due to the contact (pressing) of the pattern portion 104 with the imprint material 105 on the substrate 106, the points of interest are generally shifted outward. FIGS. 6A and 6B exemplarily show the relationship between the position in the X direction and the distortion shown in FIGS. 5A and 5B, respectively. The abscissa represents the position in the X direction, and the ordinate exemplarily shows the size and direction of the distortion at each position.

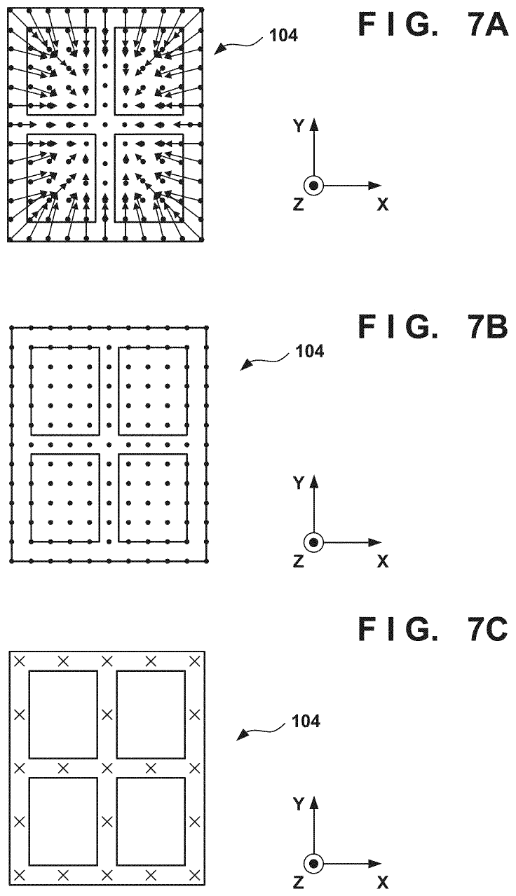

In step S205, the information processing apparatus 200 generates pattern portion data for reducing and preferably canceling the distortion of the pattern portion 104 calculated in step S204. Here, the pattern portion data can include, for example, data indicating the shape of the pattern portion 104 and the position of each pattern (for example, a line pattern or a contact pattern) arranged in the pattern portion 104. FIG. 7A shows the visualized pattern portion data for reducing or canceling the distortion of the pattern portion 104 shown in FIG. 5B. FIG. 7B shows the shift of each pattern to be formed on the shot region of the substrate 106 in step S207 using the mold 103 with the pattern portion 104 created thereon in subsequent step S206 based on the pattern portion data shown in FIG. 7A. In FIG. 7C, the arrangement of each alignment mark is indicated by an X mark.

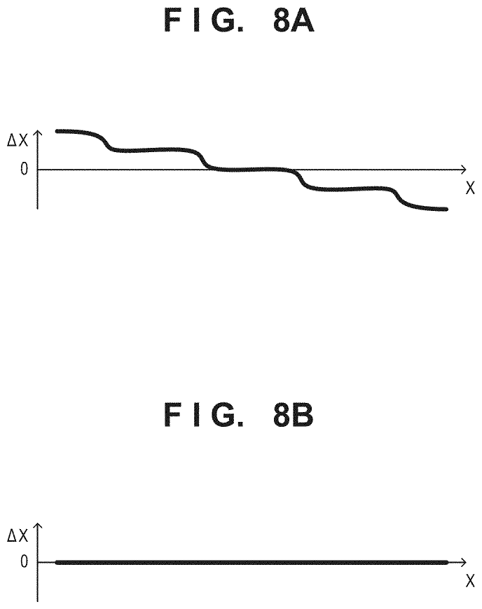

In FIG. 7A, the length and direction of each arrow represent the shift of the point of interest to be intentionally applied to the pattern portion 104, that is, the distortion to be intentionally applied to the pattern portion 104. As shown in FIG. 7B, by using the mold 103 created based on the pattern portion data shown in FIG. 5B, it is possible to reduce the pattern shift caused by the contact between the imprint material 105 and the pattern portion 104. FIGS. 8A and 8B show the relationship between the position in the X direction and the distortion shown in FIGS. 7A and 7B, respectively. The abscissa represents the position in the X direction, and the ordinate represents the size and direction of the pattern shift at each position.

In step S205, the information processing apparatus 200 generates data for reducing the distortion based on the designed pattern information and the distortion of the mold 103 (pattern portion 104) in the planar direction obtained in step S204. For example, the information processing apparatus 200 can generate the pattern portion data for reducing the distortion by multiplying the distortion of the mold 103 (pattern portion 104) in the planar direction obtained in step S204 by −1 and adding it to the designed pattern information.

In step S206, the mold 103 is created by forming a pattern in the pattern portion 104 based on the data generated in step S205. In step S207, a pattern is formed on each shot region of the substrate 106 by the imprint process in the imprint apparatus 100 using the mold 103 created in step S206. Here, by creating the mold 103 according to the above-described method, it is possible to eliminate, reduce, or minimize deformation of the shot region and/or the pattern portion 104 by the deformation mechanism of the substrate and/or the mold in the imprint process in step S207. In addition, a simplified imprint apparatus may not include such a deformation mechanism. In such an imprint apparatus, the relative position and rotation between the shot region and the pattern portion 104 may be adjusted based on the measurement results of the plurality of alignment marks, and the shape difference between the shot region and the pattern portion 104 is not considered.

Steps S201 to S207 are included in an example of the adjusting step of adjusting, in accordance with the shape information indicating the shape of the surface of the pattern portion 104 in the thickness direction of the pattern portion 104 in the contact state, the distortion of the pattern portion 104 in the planar direction.

The description so far has been made on the assumption that the substrate 106 is held by the substrate chuck 107 with sufficient strength so the deformation of the substrate 106 in a state in which the imprint material 105 and the pattern portion 104 are in contact with each other can be ignored. However, the substrate 106 can float from the substrate chuck 107 due to, for example, the small capacity of the substrate back pressure adjuster 111 with respect to the capillary force at the time of filling the pattern of the pattern portion 104 with the imprint material 105. Due to this floating, similar to the mold 103, the substrate 106 is locally deformed in the thickness direction. In such a case, it is desirable to calculate the distortion of the substrate 106 in the planar direction in addition to the distortion of the mold 103 in the planar direction in the contact state and, based on the difference between these distortions, adjust at least one of the distortion of the pattern portion 104 and the distortion of the substrate 106.

Similar to the calculation of the distortion of the pattern portion 104 in the planar direction in the contact state, the distortion of the shot region of the substrate 106 in the planar direction in the contact state can be calculated based on the shape of the surface of the shot region of the substrate 106 in the thickness direction in the contact state.

To summarize the above, according to the adjusting step of the first embodiment, first, the shape information indicating the shape of the surface of at least one of the shot region and the pattern portion in the thickness direction of the pattern portion in the contact state is acquired. According to the adjusting step of the first embodiment, then, in accordance with the shape information, at least one of the distortion of the shot region in the planar direction and the distortion of the pattern portion in the planar direction is adjusted.

An imprint method of a first example, in which the above-described first embodiment was more specifically executed, will be described below. As a blank mold for manufacturing the mold 103, a blank mold made of synthetic quartz and including the pattern portion 104 having a thickness of 1 mm and external dimensions of 26 mm and 33 mm in the X and Y directions, respectively, was prepared.

As the substrate 106, an Si wafer having a diameter of 300 mm conforming to the SEMI standard was prepared. The dimensions in the X and Y directions of the shot region 301 are 26 mm and 33 mm, respectively. These dimensions coincide with the dimensions of the pattern portion 104. The substrate 106 includes a patterned layer, and this layer forms the convex portion 302. The convex portion 302 has a height of 25 nm, and a width of 100 μm over the entire circumference.

As the imprint material 105, a UV-curable composition having a viscosity of 5 cP was used. The imprint material 105 was arranged on the shot region 301 such that the residual film portion (the portion between the convex portion of the pattern portion 104 and the surface of the substrate 106 facing it in the contact state) had a thickness of 20 nm. An inkjet type dispenser was used as the dispenser 112 to discretely arrange the imprint material 105 on the shot region 301. The imprint material 105 was arranged with a uniform density over the entire region of the shot region 301 so as to uniformly spread in the contact state.

As to the process conditions for bringing the pattern portion 104 into contact with the imprint material 105, the pressing force was 3 N, the pressing time was 5 sec, the back pressure of the mold 103 was +5 kPa, and the back pressure of the substrate 106 was −90 kPa. It has been confirmed that the substrate 106 does not float from the substrate chuck 107 when the back pressure of the substrate 106 is set to −90 kPa.

The surface shape of the imprint material 105 in the thickness direction in the contact state was calculated by applying the above information to a prediction formula based on past processing results. More specifically, the film thickness of the imprint material 105 on the convex portion 302 of the substrate 106 was 5 nm, the width of the slope 401 was 1.2 mm on each side, and the film thickness in other portions was 20 nm. FIG. 13A shows the unevenness of the surface of the substrate 106 by gradation. FIG. 13B shows the unevenness of the surface of the pattern portion 104 of the mold 103 or the imprint material 105 by gradation.

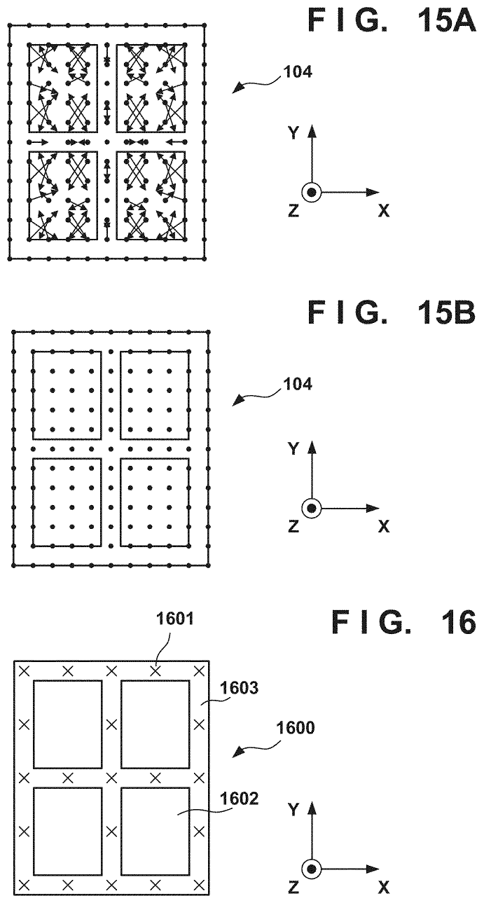

Then, based on the surface shape of the imprint material 105 in the thickness direction obtained by the calculation and the information on the shape and material of the mold 103, the distortion of the mold 103 in the planar direction was calculated using a structural analysis tool. Specifically, a three-dimensional model was created on a computer based on the outer shape and material of the mold 103, and a finite element method analysis was performed while using the vertical direction component (Z-direction coordinate) of the shape of the surface of the imprint material 105 as the forced displacement to calculate the moving amount of each point on the surface of the pattern portion 104 in the planar direction. More specifically, Abaqus manufactured by Dassault Systèmes was used as the finite element method analysis software, and the shift amount of each point on the surface of the pattern portion 104 in the planar direction shown in FIGS. 5B and 6B was calculated from the surface shape of the pattern portion 104 in the thickness direction shown in FIG. 13B. It can be seen that a complicated deformation occurs, which is difficult to predict from the result of the alignment measurement using the alignment marks arranged as exemplarily shown in FIG. 16.

Next, based on the distortion of the mold 103 in the planar direction obtained by the calculation and the designed pattern information, pattern portion data for canceling the distortion was calculated. More specifically, the coordinates obtained by subtracting the shift amount of each point on the surface of the pattern portion 104 in the planar direction from the X and Y coordinates of each point of the designed pattern were set as the X and Y coordinates of each point of the corrected pattern.

Next, the pattern portion 104 of the mold 103 was formed using the pattern portion data obtained by the calculation. When forming the pattern portion 104, electron beam lithography and an etching step was used as in manufacturing a general photomask for semiconductor manufacturing.

Using the mold 103 created as described above, a pattern made of a cured product of the imprint material 105 was formed on each shot region 301 of the substrate 106 using the imprint apparatus 100. The overlay accuracy (overlay error) between the obtained pattern made of the cured product of the imprint material 105 and the underlying pattern on the substrate 106 was checked using an overlay inspection apparatus. As a result, the overlay accuracy was 15.8 nm when the mold 103 with the designed pattern intact formed thereon was used, whereas it was 8.2 nm when the mold 103 created in this example was used, showing a significant improvement. The yield improved from 92.7% to 96.9%.

An imprint apparatus and an imprint method according to the second embodiment of the present invention will be described below. Note that matters not mentioned as the second embodiment can follow the first embodiment. FIG. 9 shows the arrangement of an imprint apparatus 100′ according to the second embodiment. The imprint apparatus 100′ according to the second embodiment can include a mold distortion adjusting unit 901 which adjusts the distortion of a mold 103 (a pattern portion 104 thereof) and a substrate distortion adjusting unit 902 which adjusts the distortion of a substrate 106 (a shot region thereof). The mold distortion adjusting unit 901 and the substrate distortion adjusting unit 902 may be understood to form a distortion adjusting unit which reduces or adjusts the difference between the distortion of the pattern portion 104 of the mold 103 and the distortion of the shot region of the substrate 106. Note that by adjusting these distortions, adjustment (magnification correction) of the difference in size between the mold 103 (the pattern portion 104 thereof) and the substrate 106 (the shot region thereof) can also be performed at the same time.

For example, the mold distortion adjusting unit 901 adjusts the distortion of the pattern portion 104 by deforming the mold 103 by applying a force in the planar direction to the side surface of the mold 103. For example, as disclosed in Japanese Patent No. 5932286, the substrate distortion adjusting unit 902 irradiates the substrate 106 with light having a controlled intensity distribution using a DMD (Digital Mirror Device), thereby adjusting the distortion of the shot region of the substrate 106 by the temperature distribution thus formed. In the example shown in FIG. 9, a curing unit 108 is configured to irradiate an imprint material 105 with light as curing energy, and light from the curing unit 108 and light from the substrate distortion adjusting unit 902 are combined by the half mirror.

The imprint apparatus 100′ can include a surface shape acquisition unit 906, a distortion calculation unit 905, and a distortion control unit 904. The surface shape acquisition unit 906 acquires the surface shapes of the mold 103 and the substrate 106 in the thickness direction. The distortion calculation unit 905 calculates the distortions of the mold 103 and the substrate 106 in the planar direction. The distortion control unit 904 controls the mold distortion adjusting unit 901 and the substrate distortion adjusting unit 902 based on the distortions calculated by the distortion calculation unit 905. The surface shape acquisition unit 906, the distortion calculation unit 905, and the distortion control unit 904 may be incorporated in a control unit 113.

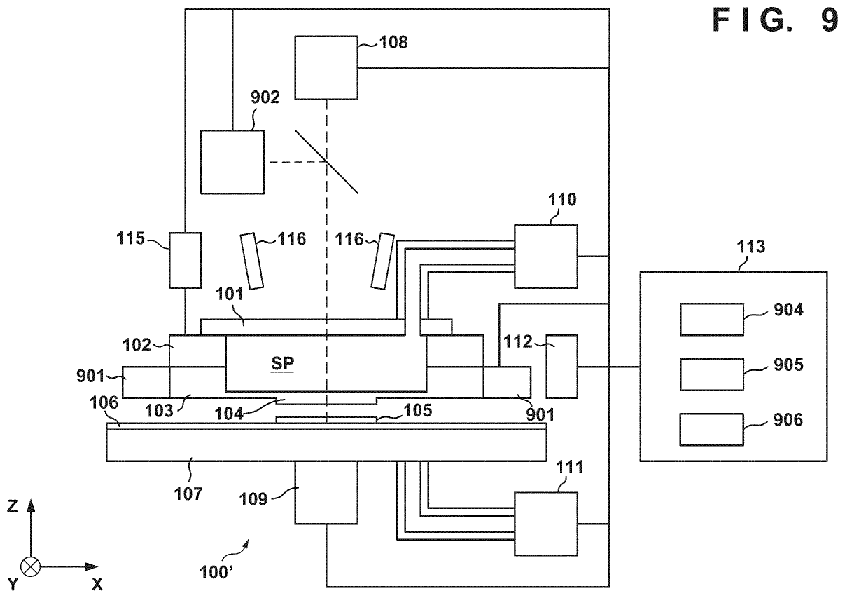

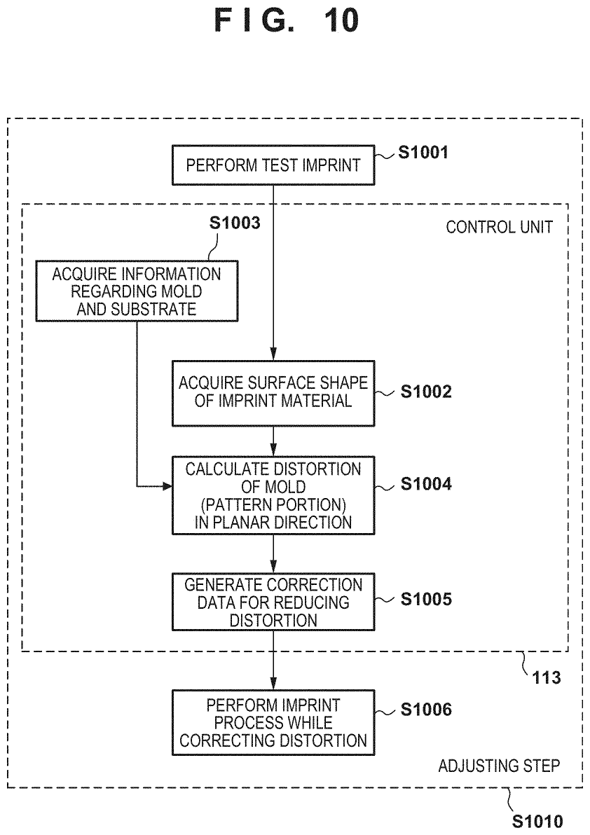

FIG. 10 illustrates the procedure of an imprint method S1010 according to the second embodiment of the present invention. Steps S1002 to S1005 are included in an information processing step and, typically, can be performed by the control unit 113 that can be formed by a computer installed with a program. An example in which the information processing step is performed by the control unit 113 will be described below. The control unit 113 can include a CPU, and a memory storing a program for performing steps S1002 to S1005. The program can be transferred via a telecommunication line, or provided via a memory medium such as a semiconductor memory or an optical disk. Note that the present invention does not exclude a case in which all or part of the information processing step is performed by manual calculation.

In step S1001, a test imprint step is performed in which the imprint apparatus 100′ uses the mold 103 to perform an imprint process on a shot region of a test substrate and form a cured product of an imprint material. The test substrate may be the same substrate as the substrate 106 on which an imprint process is performed in step S1005, or may be a substrate different from the substrate 106. In the test imprint step, alignment measurement can be performed using alignment marks provided on the shot region of the test substrate and alignment marks provided on the mold 103. Further, based on the alignment measurement result, the distortion of the pattern portion 104 of the mold 103 and the distortion of the shot region of the substrate 106 can be adjusted by the mold distortion adjusting unit 901 and the substrate distortion adjusting unit 902, respectively. Thus, the shot region of the substrate 106 and the pattern portion 104 of the mold 103 are overlaid with each other.

In step S1002, the control unit 113 (surface shape acquisition unit 906) acquires, from a measuring apparatus, information indicating the shape of the surface of the pattern made of the cured product of the imprint material 105 formed on the test substrate in step S1001 (test imprint step). This information can be acquired by measuring the pattern formed on the test substrate. As the measurement method, in addition to the method using the measuring apparatus such as an optical measuring apparatus or a stylus measuring apparatus, a method of measuring the film thickness of the cured product of the imprint material 105 by a film thickness measuring apparatus such as an ellipsometry, and adding the result to the surface height distribution of the test substrate is useful. The surface shape acquisition unit 906 may be the measuring apparatus as described above, and in this case, the surface shape acquisition unit 906 can be separated from the control unit 113.

In step S1003, the control unit 113 acquires member information which is information regarding the mold 103 and the substrate 106. The member information can include, for example, information on the shape of the mold 103 in the thickness direction, the shape of the mold 103 in the planar direction, the shape of the substrate 106 in the thickness direction, and the shape of the substrate 106 in the planar direction. The member information can further include information on the material, Young's modulus, Poisson's ratio, or the like of each of the mold 103 and the substrate 106.

In step S1004, the control unit 113 (distortion calculation unit 905) calculates the distortion of the pattern portion 104 of the mold 103 in the planar direction based on the member information acquired in step S1003 and the surface shape of the imprint material 105 obtained in step S1002. Here, the influence of the shape of the surface of the pattern portion 104 in the thickness direction on the distortion of the pattern portion 104 in the planar direction will be described.

FIG. 11A exemplarily shows the relationship between the position in the X direction and distortion of the pattern portion 104 in a state (non-contact state) in which the pattern portion 104 is not in contact with the imprint material 105 on the substrate 106. FIG. 11B exemplarily shows the relationship between the position in the X direction and the distortion of the pattern portion 104 in a state (contact state) in which the pattern portion 104 is in contact with the imprint material 105 on the substrate 106. In FIGS. 11A and 11B, the abscissa represents the position in the X direction, and the ordinate exemplarily shows the size and direction of the distortion at each position. In this example, the distortion of the pattern portion 104 of the mold 103 and the distortion of the shot region of the substrate 106 have been adjusted by the mold distortion adjusting unit 901 and the substrate distortion adjusting unit 902, respectively, in the test imprint step. Therefore, the distortion has been corrected to zero at the left end and the right end of the pattern portion 104. On the other hand, in the region other than the left end and the right end of the pattern portion 104, a high-order spatial-frequency distortion exists. This distortion can be calculated by the method similar to that in the first embodiment.

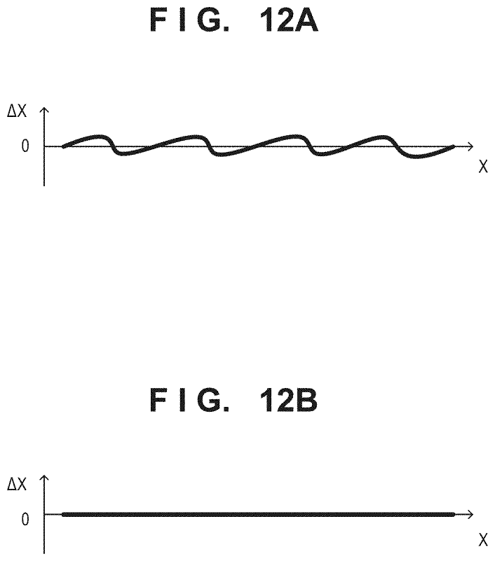

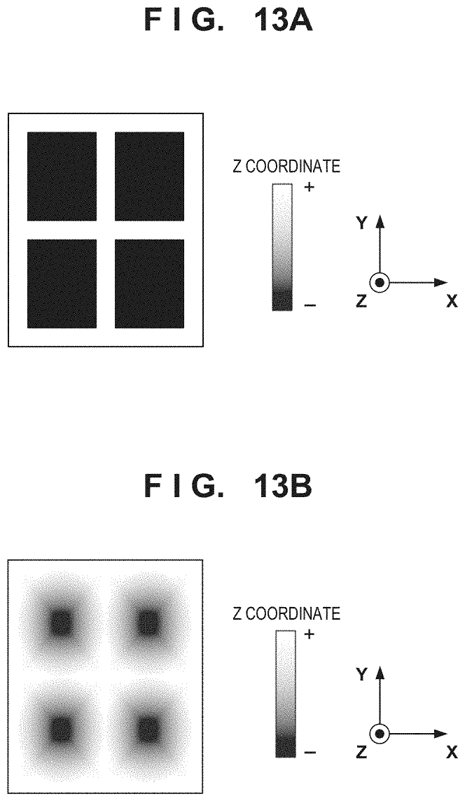

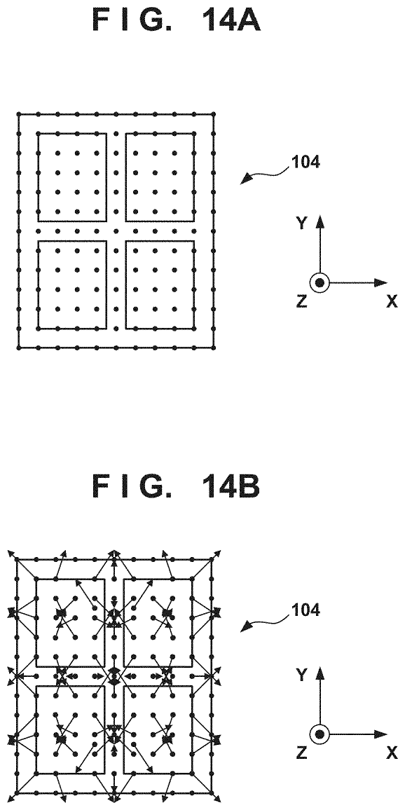

FIGS. 14A and 14B are plan views of the pattern portion 104 corresponding to FIGS. 4A and 4B, respectively. In FIG. 14A, each black circle exemplifies a point of interest in the pattern portion 104 in a state (non-contact state) in which the pattern portion 104 is not in contact with the imprint material 105 on the substrate 106. In FIG. 14B, the length and direction of each arrow exemplify the shift of the point of interest in the pattern portion 104 in a state (contact state) in which the pattern portion 104 is in contact with the imprint material 105 on the substrate 106, that is, the distortion of the pattern portion 104. It can be seen that a complicated deformation occurs, which is difficult to predict from the result of the alignment measurement using the alignment marks arranged as exemplarily shown in FIG. 16.

In step S1005, the control unit 113 (distortion control unit 904) generates correction data for reducing and preferably canceling the distortion of the pattern portion 104 calculated in step S1004. More specifically, as exemplarily shown in FIG. 12A, the control unit 113 (distortion control unit 904) can correct correction data for controlling the mold distortion adjusting unit 901 so as to apply a distortion obtained by multiplying the distortion calculated in step S1004 by −1. With this operation, as exemplarily shown in FIG. 12B, it is possible to reduce the pattern shift caused by the contact between the imprint material 105 and the pattern portion 104, and improve the overlay accuracy. FIG. 15A exemplarily shows the distortion applied to the pattern portion 104 of the mold 103 by the mold distortion adjusting unit 901 in a state (non-contact state) in which the pattern portion 104 is not in contact with the imprint material 105 on the substrate 106. FIG. 15B exemplarily shows the distortion of the pattern portion 104 of the mold 103 in a state (contact state) in which the pattern portion 104 is in contact with the imprint material 105 on the substrate 106.

In order to improve the overlay accuracy, it is not necessary to adjust both the shot region and the pattern portion 104 in accordance with the designed target, but it is important to adjust the relative position between the pattern on the shot region and the pattern of the pattern portion 104. Therefore, instead of adjusting the distortion of the pattern portion 104 of the mold 103 by the mold distortion adjusting unit 901, the distortion of the shot region 301 of the substrate 106 may be adjusted by the substrate distortion adjusting unit 902.

Alternatively, the distortion of the pattern portion 104 of the mold 103 may be adjusted by the mold distortion adjusting unit 901, and the distortion of the shot region 301 of the substrate 106 may be adjusted by the substrate distortion adjusting unit 902. Further, the low-order (or high-order) spatial-frequency distortion may be adjusted by the mold distortion adjusting unit 901, and the high-order (or low-order) spatial-frequency distortion may be adjusted by the substrate distortion adjusting unit 902.

According to the second embodiment, even when the local unevenness of the underlying substrate 106 has changed, it is unnecessary to newly create a mold, and the good overlay accuracy can be obtained by controlling the imprint apparatus 100′. Therefore, it is possible to improve the yield and the device performance while reducing the manufacturing cost.

Also in the second embodiment, it is possible to improve the overlay accuracy between the pattern on the substrate 106 and a pattern to be formed thereon by the imprint process (or the pattern of the pattern portion 104) in the region where no alignment mark exists. Therefore, even if the numerical values of the overlay inspection are the same as in the conventional method, it is possible to improve the yield and the device performance.

The first embodiment and the second embodiment are different in the method of acquiring the shape of the surface of the mold 103 in the thickness direction and the method of correcting the distortion in the planar direction, but they may be mutually changed. For example, the shape of the surface of the mold 103 in the thickness direction may be calculated based on the member information as illustrated in the first embodiment, and the distortion of at least one of the mold 103 and the substrate 106 may be adjusted based thereon in the imprint apparatus. Alternatively, the shape of the surface of the mold 103 in the thickness direction may be measured as illustrated in the second embodiment, and the pattern portion may be manufactured based thereon.

An imprint method of a second example, in which the above-described second embodiment was more specifically executed, will be described below. A description of matters in the second example common to the first example will be omitted, and matters unique to the second example will be described.

Test imprinting was performed on a test substrate using the imprint apparatus 100′ shown in FIG. 9 under the same conditions as in the first example. The second example is different from the first example in two points. One is that the mold 103 obtained by processing the surface of the pattern portion 104 to form the designed pattern intact thereon was used. The other is that the mold was distorted using the mold distortion adjusting unit 901 with reference to the alignment marks at the four corners of each of the pattern portion 104 and the shot region 301, and adjusted such that the outer shapes of the pattern portion 104 and the shot region 301 overlay with each other.

Next, the surface of the cured product of the imprint material 105 obtained by the test imprinting was measured over the entire region of the shot region 301 using a surface profiler by a white interference method, and information indicating the surface shape of the cured product was acquired. Then, based on the acquired surface shape and the shape/material information of the mold 103, the distortion of the mold 103 in the planar direction was calculated by structural analysis. The difference from the first example is that the outer periphery of the pattern portion 104 was fixed in the analysis model.

Next, based on the distortion of the mold 103 in the planar direction obtained by the calculation, correction data for reducing or canceling the distortion was generated. More specifically, the distortion to be applied to an arbitrary point on the surface of the pattern portion 104 was set to have the same magnitude but the opposite direction in the planar direction as the distortion of the mold 103 in the planar direction obtained by the calculation.

Next, a pattern was formed by an imprint process on the substrate 106 in the imprint apparatus 100′ while correcting the distortion in accordance with the correction data. The substrate distortion adjusting unit 902 was used to correct the distortion. At this time, since the correction data was for the mold 103 side, the correction amount for the substrate 106 side was set to have the same magnitude but the opposite direction in the planar direction as the correction data, that is, set to be the same value as the distortion of the mold 103 which was previously calculated.

The overlay accuracy (overlay error) between the obtained pattern made of the cured product of the imprint material 105 and the underlying pattern on the substrate 106 was checked using an overlay inspection apparatus. As a result, the overlay accuracy at the time of test imprinting was 11.7 nm, whereas it was 4.8 nm with the pattern formed in the second example, showing a significant improvement. The yield improved from 94.8% to 98.6%.

An article manufacturing method as an application example of the imprint apparatus or the imprint method described above will be described below.

The pattern of a cured product formed using an imprint apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, an SRAM, a flash memory, and an MRAM and semiconductor elements such as an LSI, a CCD, an image sensor, and an FPGA. Examples of the optical element include a microlens, a light guide, a waveguide, an antireflection film, a diffraction grating, a polarizing element, a color filter, a light emitting element, a display, and a solar cell. Examples of the MEMS include a DMD, a microchannel, and an electromechanical conversion element. Examples of the recording element include an optical disk such as a CD or a DVD, a magnetic disk, a magneto-optical disk, and a magnetic head. Examples of the sensor include a magnetic sensor, an optical sensor, and a gyro sensor. The mold includes an imprint mold or the like.

The pattern of the cured product is directly used as at least some of the constituent members of the above-described articles or used temporarily as a resist mask. After etching or ion implantation is performed in the substrate processing step, the resist mask is removed.

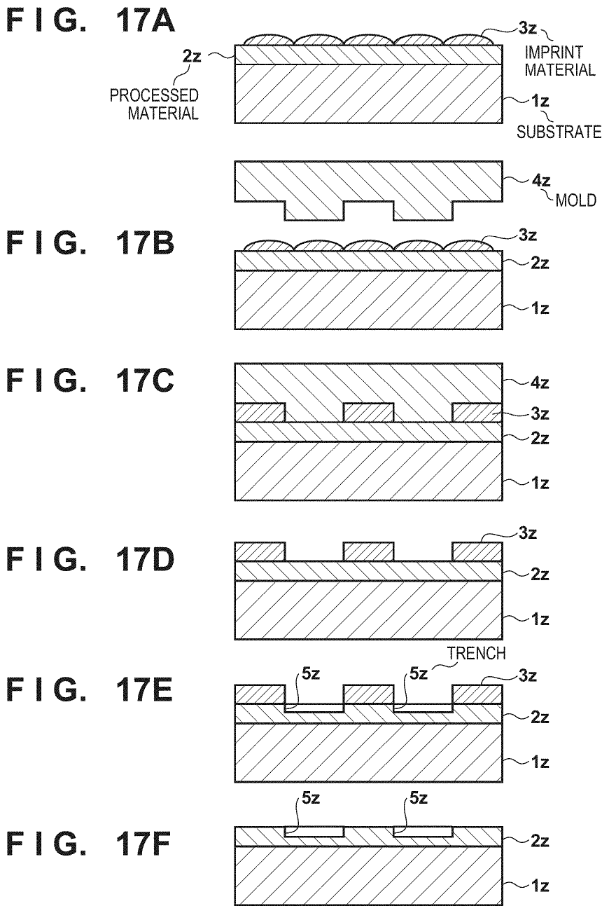

An article manufacturing method in which an imprint apparatus forms a pattern on a substrate, processes the substrate on which the pattern is formed, and manufactures an article from the processed substrate will be described next. As shown FIG. 17A, a substrate 1z such as a silicon wafer with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

As shown in FIG. 17B, a side of a mold 4z for imprint with a concave-convex pattern is directed toward and made to face the imprint material 3z on the substrate. As shown in FIG. 17C, the substrate 1z to which the imprint material 3z is applied is brought into contact with the mold 4z, and a pressure is applied. The gap between the mold 4z and the processed material 2z is filled with the imprint material 3z. In this state, when the imprint material 3z is irradiated with light as energy for curing via the mold 4z, the imprint material 3z is cured.

As shown in FIG. 17D, after the imprint material 3z is cured, the mold 4z is separated from the substrate 1z, and the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the concave-convex pattern of the mold 4z is transferred to the imprint material 3z.

As shown in FIG. 17E, when etching is performed using the pattern of the cured product as an etching resistant mask, a portion of the surface of the processed material 2z where the cured product does not exist or remains thin is removed to form a groove 5z. As shown in FIG. 17F, when the pattern of the cured product is removed, an article with the grooves 5z formed in the surface of the processed material 2z can be obtained. Here, the pattern of the cured product is removed. However, instead of removing the pattern of the cured product after the process, it may be used as, for example, an interlayer dielectric film included in a semiconductor element or the like, that is, a constituent member of an article.

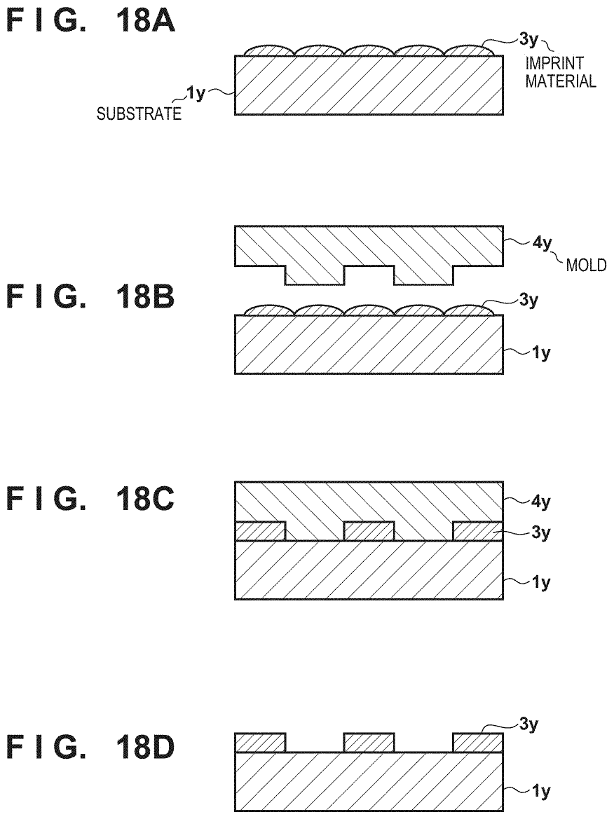

Another article manufacturing method will be described next. As shown FIG. 18A, a substrate 1y such as silica glass is prepared. Next, an imprint material 3y is applied to the surface of the substrate 1y by an inkjet method or the like. A layer of another material such as a metal or a metal compound may be provided on the surface of the substrate 1y.

As shown in FIG. 18B, a side of a mold 4y for imprint with a concave-convex pattern is directed toward and made to face the imprint material 3y on the substrate. As shown in FIG. 18C, the substrate 1y to which the imprint material 3y is applied is brought into contact with the mold 4y, and a pressure is applied. The gap between the mold 4y and the substrate 1y is filled with the imprint material 3y. In this state, when the imprint material 3y is irradiated with light via the mold 4y, the imprint material 3y is cured.

As shown in FIG. 18D, after the imprint material 3y is cured, the mold 4y is separated from the substrate 1y, and the pattern of the cured product of the imprint material 3y is formed on the substrate 1y. Thus, an article including the pattern of the cured product as a constituent member can be obtained. Note that when the substrate 1y is etched using the pattern of the cured product as a mask in the state shown in FIG. 18D, an article with the concave and convex portions reversed with respect to the mold 4y, for example, an imprint mold can be obtained.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. An imprint method of performing an imprint process for curing an imprint material in a state in which the imprint material on a shot region of a substrate and a pattern portion of a mold are in contact with each other, the method comprising:
an adjusting step of adjusting, in accordance with shape information indicating a shape of a surface of at least one of the shot region and the pattern portion in a thickness direction of the pattern portion in the state, at least one of a distortion of the shot region in a planar direction orthogonal to the thickness direction and a distortion of the pattern portion in the planar direction.

2. The imprint method according to claim 1, wherein
in the adjusting step, the shape information is acquired based on the shape of the surface of the shot region in the thickness direction.

3. The imprint method according to claim 2, wherein
the shape of the surface of the shot region in the thickness direction in the state is a shape of the surface of the shot region in a state in which the substrate is held by a substrate chuck.

4. The imprint method according to claim 1, further comprising a test imprint step of forming a cured product of the imprint material on a test substrate by the imprint process,
wherein in the adjusting step, the shape information is acquired based on a shape of a surface of the cured product in the thickness direction.

5. The imprint method according to claim 1, wherein
in the adjusting step, the mold is manufactured in accordance with the shape information such that the pattern portion includes a pattern that reduces the distortion in the planar direction in the state.

6. The imprint method according to claim 1, wherein
in the adjusting step, at least one of the shape of the shot region in the planar direction and the distortion of the pattern portion in the planar direction is adjusted in accordance with the shape information in the imprint process.

7. The imprint method according to claim 1, wherein
the shot region includes a patterned layer, and the shape of the shot region in the thickness direction in the state includes unevenness by the patterned layer, and
the shape information includes information indicating the unevenness.

8. The imprint method according to claim 1, wherein
the pattern portion includes an alignment mark, and the shape information includes information indicating positions of a plurality of portions in the thickness direction, the portions being located in a region of the pattern portion where the alignment mark does not exist.

9. An article manufacturing method comprising:
a step of forming a pattern on a substrate using an imprint method defined in claim 1; and
a step of performing a process on the substrate with the pattern formed thereon in the step of forming,
wherein the article is manufactured from the substrate having undergone the process.

10. An imprint apparatus that performs an imprint process for curing an imprint material in a state in which the imprint material on a shot region of a substrate and a pattern portion of a mold are in contact with each other, the apparatus comprising:
a distortion adjusting unit configured to adjust, in accordance with shape information indicating a shape of a surface of at least one of the shot region and the pattern portion in a thickness direction of the pattern portion in the state, at least one of a distortion of the shot region in a planar direction orthogonal to the thickness direction and a distortion of the pattern portion in the planar direction.

11. A method of a manufacturing mold, wherein
the mold is configured to be used in an imprint process for curing an imprint material in a state in which the imprint material on a shot region of a substrate and a pattern portion of the mold are in contact with each other, and
the manufacturing method comprises a step of forming, in the pattern portion, a pattern in which a distortion in a planar direction orthogonal to a thickness direction of the pattern portion has been adjusted in accordance with shape information indicating a shape of a surface of at least one of the shot region and the pattern portion in the thickness direction in the state.
